(19) United States
(12) Patent Application Publication
(10) Pub. No.: US 2008/0237693 A1
(43) Pub. Date: Oct. 2, 2008

(54) Storage of non-volatile memory device and method of forming the same

(75) Inventors: Jang-Eun Lee, Suwon-si (KR); Se-Chung Oh, Suwon-si (KR); Kyung-Tae Nam, Suwon-si (KR); Jun-Ho Jeong, Suwon-si (KR); Dae-Kyom Kim, Daejeon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/078,255

(22) Filed: Mar. 28, 2008

(30) Foreign Application Priority Data
Mar. 30, 2007 (KR) 10-2007-0031493

(51) Int. Cl. H01L 29/788; H01L 21/28

(52) U.S. Cl. 257/321; 438/594; 257/E29.3; 257/E21.179

(57) ABSTRACT

There is provided a storage of a non-volatile memory device and a method of forming the same. The storage of example embodiments may include a bottom electrode, a first tunneling insulating layer on the bottom electrode, a middle electrode on the first tunneling insulating layer, a second tunneling insulating layer on the middle electrode, and a top electrode on the second tunneling insulating layer. The first and second tunneling insulating layers may be formed of metal oxide having a thickness from about several Å to about several tens Å and a storage may be formed to have a width of about several tens nm. Therefore, a multi bit storage, increased integration, increased operation speed and decreased power consumption may be realized.

### PRIORITY STATEMENT

This U.S. non-provisional patent application claims priority under 35 U.S.C. §119 to Korean Patent Application No. 10-2007-0031493, filed on Mar. 30, 2007, in the Korean Intellectual Property Office (KIPO), the entire contents of which are herein incorporated by reference.

### BACKGROUND

1. Field

Example embodiments disclosed herein relate to semiconductors devices and methods of forming the same, and more particularly, to a non-volatile memory device and a method of forming the same.

2. Description of the Related Art

A requirement for a semiconductor device which may be suitable for a variety of application fields, and allows for large capacity, miniaturization, increased speed, decreased power operation, and increased integration, is progressing.

For example, structures, e.g., a ferroelectric RAM (FeRAM), a magnetic RAM (MRAM) or an Ovonic unified RAM (OUM), may be introduced as a next generation non-volatile memory device. The ferroelectric RAM using a self polarization phenomenon may have advantages of decreased power consumption and increased speed operation but may have problems of increased cost and undesirable data retention. The MRAM may be a ferromagnetic tunneling device using a giant magneto resistive (GMR) effect. The MRAM may have increased power consumption for magnetization reverse and a limitation of increased integration. A phase changeable RAM (PRAM), e.g., the OUM, may have a disadvantage of increased power consumption for a switching current. A resistive RAM (RRAM) using an electric pulse induced resistive (EPIR) effect was introduced as a more advanced technology compared with the above devices. The RRAM may have advantages of decreased power consumption, increased integration and a multi bit realization according to an extensive resistance change.

In an EPIR device, Pr₁₋ₓCaₓMnO₃ (PCMO), La₁₋ₓCaₓMnO₃, La₁₋ₓSrₓMnO₃, or Gd_{0.7}Ca_{0.3}Co₂O_{5.5} having a perovskite structure, which may be based on an oxygen eight-sided network including a 3d transition metal element at its center, may be used as a variable resistor, and the PCMO including a composition, where x may be near about 0.3, may have a most extensive resistance change. However, forming the uniform PCMO of the perovskite structure may be difficult and a subsequent process of about 400° C. or more may not be performed due to deterioration of the variable resistor. When a resistance decreases, a pulse of about 1 μs˜about 100 μs and a voltage of about 0.5V˜about 10V may be required, and when a resistance increases, a pulse of about 10 ns˜about 1,000 ns and a voltage of about 1.5 times˜about 2.5 times as high as the voltage of when a resistance decreases, may be required.

### SUMMARY

Example embodiments provide a storage of a non-volatile memory device having a dual insulating layer which may include a bottom electrode, a first tunneling insulating layer on the bottom electrode, a middle electrode on the first tunneling insulating layer, a second tunneling insulating layer on the middle electrode, and a top electrode on the second tunneling insulating layer.

Example embodiments provide a method of forming a storage of a non-volatile memory device having a dual insulating layer which may include forming a first tunneling insulating layer on a bottom layer, forming a middle electrode on the first tunneling insulating layer on a bottom layer, forming a second tunneling insulating layer on the middle electrode, and forming a top electrode on the second tunneling insulating layer.

### BRIEF DESCRIPTION OF THE FIGURES

Example embodiments will be more clearly understood from the following detailed description taken in conjunction with the accompanying drawings. FIGS. 1-18 represent non-limiting, example embodiments as described herein.

FIGS. 1-2 are cross sectional views of a storage of a non-volatile memory device according to example embodiments.

FIGS. 3-17 are cross sectional views illustrating methods of forming a storage of a non-volatile memory device according to example embodiments.

FIG. 18 is a graph showing an operation characteristic of a non-volatile memory device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will be described below in more detail with reference to the accompanying drawings. Example embodiments may, however, be embodied in different forms and should not be constructed as limited to the embodiments set forth herein. Rather, these embodiments may be provided so that this disclosure will be thorough and complete, and will fully convey the scope of example embodiments to those skilled in the art.

In the figures, the dimensions of layers and regions may be exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

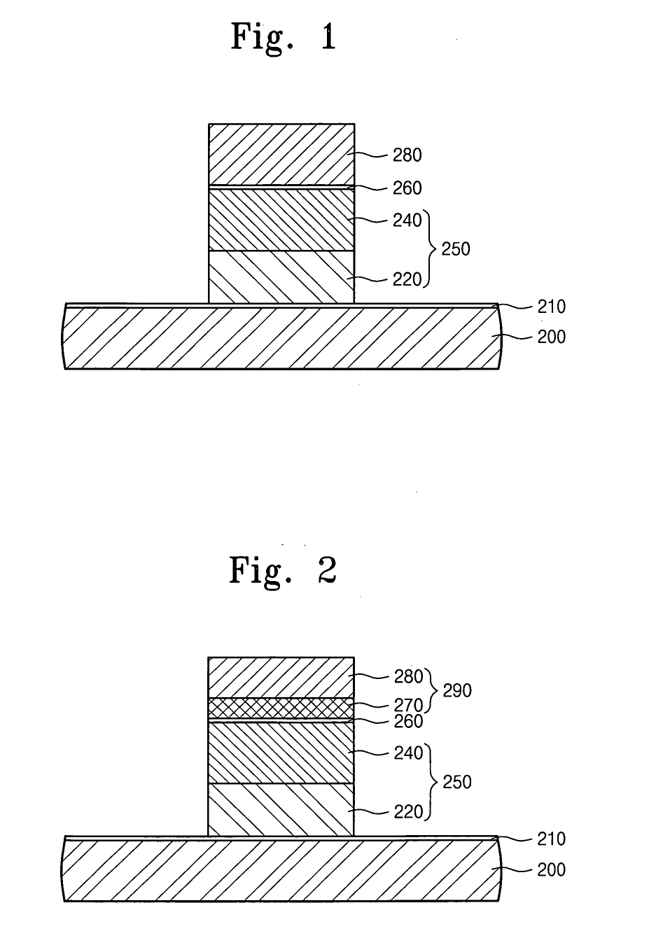

FIG. 1 is a cross sectional view of a storage of a non-volatile memory device according to example embodiments. Referring to FIG. 1, the storage may include a bottom electrode 200, a first tunneling insulating layer 210 on the bottom electrode 200, a middle electrode 250 on the first tunneling insulating layer 210, a second tunneling insulating layer 260 on the middle electrode 250, and a top electrode 280 on the second tunneling insulating layer 260. The first and second tunneling insulating layers 210 and 260 may not be broken by a relatively strong electric field and may have a thickness from about several Å to about several tens Å and a width of about several tens nm or less to enable charges to move by a tunneling between bands. The first and second tunneling insulating layers 210 and 260 may have a thickness from about 5 Å to about 20 Å and a width of about 100 nm or less.

When the widths of insulating layers are greater, current may increase and an over-current may flow due to a break of the insulating layers in a weak portion of the insulating layers. Breaks of the insulating layers may be suppressed below a critical dimension and an over-current phenomenon due to the breaks of the insulating layers may disappear in a pattern having a width of about 100 nm or less. Also, when the thicknesses of the insulating layers are greater, the tunneling between the bands may be limited. Thus, the thicknesses of the insulating layers may be about several tens Å or less.

In example embodiments, a physical break may be prevented or reduced by forming the first and second tunneling insulating layers 210 and 260 between the bottom electrode 200 and the top electrode 280. When one tunneling insulating layer is formed between the electrodes, a current due to a tunneling between the bands may be detected at a predetermined or given voltage or less but an over-current due to a break of the insulating layer may be detected at more than a critical voltage. When two tunneling insulating layers are formed as in example embodiments, break voltages of the insulating layers may become relatively high, because the insulating layers may act as buffer to each other. When the first and second tunneling insulating layers 210 and 260 have the same or similar tunneling resistance, this effect may be improved.

In example embodiments, the second tunneling insulating layer 260 may have a switching characteristic when a voltage is applied, and the first tunneling insulating layer 210 may be an insulating layer for controlling a breakdown of the second tunneling layer 260. Therefore, a size of the first and second tunneling insulating layers 210 and 260 may be several tens nm in order to endure even over current density of about 1×10⁴ A/cm².

Also, the first and second tunneling insulating layers 210 and 260 may be properly selected to prevent or reduce a break of the insulating layer and to switch a resistor over a predetermined or given voltage. For instance, the first and second tunneling insulating layers 210 and 260 may be a magnesium oxide layer, an aluminum oxide layer or a titanium oxide layer. The second tunneling insulating layer 260 may be a titanium oxide layer.

The middle electrode 250 may include a first middle electrode 220 and a second middle electrode 240. The first middle electrode 220 may be in contact with the first tunneling insulating layer 210 and may be formed of a platinode metal layer or magnetic material. A platinode element may be a noble metal which belongs to Group VIII of the periodic table and may include ruthenium (Ru), rhodium (Rh), palladium (Pd), osmium (Os), iridium (Ir), and platinum (Pt). The first middle electrode 220 may be formed of ruthenium (Ru), iridium (Ir), nickel (Ni), cobalt-ferrum-boron alloy or nickel-ferrum alloy.

Also, the second middle electrode 240 may be formed of a metal that provides the second tunneling insulating layer 260 with a hole trap site and may help tunneling between the bands occur in the second tunneling insulating layer 260. For instance, the second tunneling insulating layer 260, e.g., a titanium oxide layer, may be more easily formed by forming the second middle electrode 240 of a titanium layer or a titanium nitride layer.

The bottom electrode 200 may be formed of a platinode metal layer and/or magnetic material. The bottom electrode 200 may be formed of ruthenium (Ru), iridium (Ir), nickel (Ni), cobalt-ferrum-boron alloy or nickel-ferrum alloy. The bottom electrode 200 may include the magnetic material which may be in contact with the first tunneling insulating layer 210 on the platinode metal layer.

The top electrode 280 may be formed of a platinode metal layer to improve an interface characteristic of the second tunneling insulating layer 260 and may be formed of material having an etch selectivity with respect to the underlying material to more easily pattern a storage. The platinode metal layer may have an etch selectivity with respect to the titanium layer, the titanium nitride layer and the magnetic material.

The second tunneling insulating layer 260 may have a lower energy band partly by including the hole trap site. Electrons may be captured in the hole trap site. As a result, the band may rise and tunneling resistance may increase, which may be explained by a Simons-verderver model. Also, the first tunneling insulating layer 210 may have a self tunneling resistance to limit a tunneling current flowing through the second tunneling insulating layer 260. Thus, the second tunneling insulating layer 260 may be prevented or reduced from being broken at more than a predetermined or given voltage.

FIG. 2 is a cross sectional view of a storage of a non-volatile memory device according to example embodiments. Referring to FIG. 2, the storage may include a bottom electrode 200, a first tunneling insulating layer 210, a middle electrode 250, a second tunneling insulating layer 260 and a top electrode 290. The middle electrode 250 may include a first middle electrode 220 and a second middle electrode 240. The top electrode 290 may include a first top electrode 270 and a second top electrode 280. The second top electrode 280 may be formed of a platinode metal layer and the first top electrode 270 may be formed of a tantalum layer which may be in contact with the second tunneling insulating layer 260.

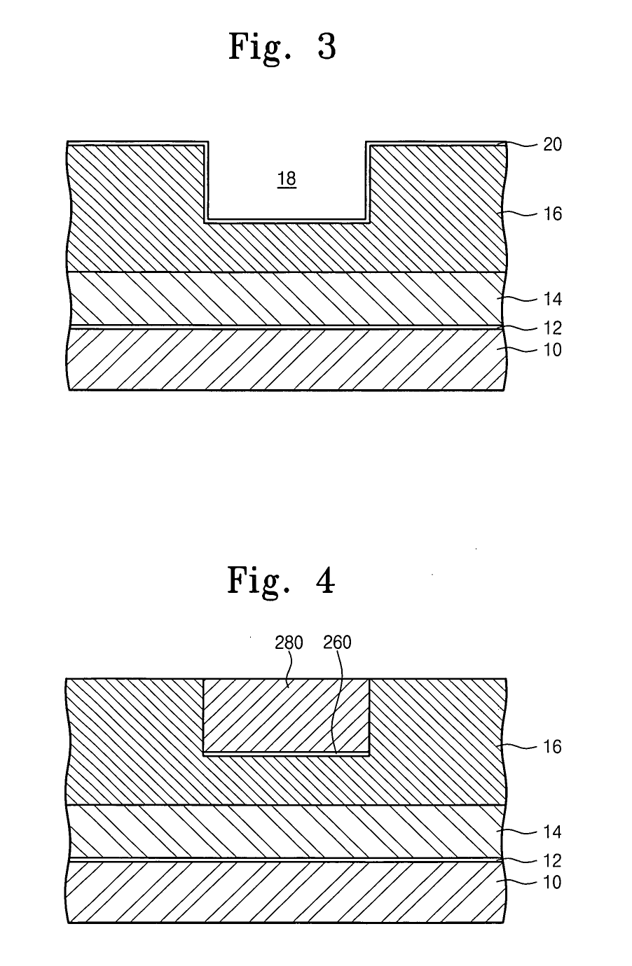

FIGS. 3 to 5 are cross sectional views illustrating a method of forming a storage of a non-volatile memory device according to example embodiments. Referring to FIG. 3, a bottom electrode layer 10, a first tunneling insulating layer 12, a first middle electrode layer 14 and a second middle electrode layer 16 may be sequentially formed. A portion of the second middle electrode layer 16 may be etched to a predetermined or given depth to form a groove 18. The bottom electrode layer 10 may be formed of a platinode metal layer or magnetic material. The bottom electrode layer 10 may also be formed by stacking the magnetic material on the platinode metal layer. A platinode element may include ruthenium (Ru), rhodium (Rh), palladium (Pd), osmium (Os), iridium (Ir), and/or platinum (Pt). The magnetic material may include cobalt-ferrum-boron alloy or nickel-ferrum alloy. The bottom electrode layer 10 may be formed of at least one stacked layer selected from a group consisting of ruthenium (Ru), iridium (Ir), nickel (Ni), cobalt-ferrum-boron alloy and nickel-ferrum alloy.

The first tunneling insulating layer 12 may be formed on the bottom electrode layer 10. The first tunneling insulating layer 12 may be formed of a metal oxide layer (e.g., a magnesium oxide layer, an aluminum oxide layer and/or a titanium oxide layer) to have a thickness of about 5 Å˜about 20 Å. The first middle electrode layer 14 may be formed on the first tunneling insulating layer 12 and the second middle electrode layer 16 may be formed on the first middle electrode layer 14. The first middle electrode layer 14 may be formed of platinode metal or magnetic material and the second middle electrode layer 16 may be formed of a titanium layer or a titanium nitride layer.

The groove 18 may be formed to have a hole shape of a maximum width of about several tens nm or less. The groove 18 may be formed to have a width of about 100 nm or less. The second middle electrode layer 16 may be etched to a predetermined or given depth to form the groove 18. As a result, sidewalls and a lower portion of the groove 18 may be formed of the second middle electrode layer 16.

A second tunneling insulating layer 20 may be formed at least on the lower portion of the groove 18. After forming the groove 18, a surface of the second middle electrode layer 16 may be oxidized to form the second tunneling insulating layer 20 by using a cleaning solution including oxygen during the cleaning process. For example, a titanium layer or a titanium nitride layer may be oxidized by a cleaning solution to form the second tunneling insulating layer 20 of a titanium oxide layer. The second tunneling insulating layer 20 may be formed to have a thickness from about several Å to about several tens Å. Thus, the second middle electrode layer 16 may be cleaned with a proper oxidation rate. Because an oxidation rate of the titanium nitride layer may be later than the titanium layer, the titanium nitride layer may be used as the second middle electrode layer 16. If the second tunneling insulating layer 20 is formed to have a thickness from about 5 Å to about 20 Å, a break in an insulating layer may be prevented or reduced, and a tunneling effect between the bands may be improved.

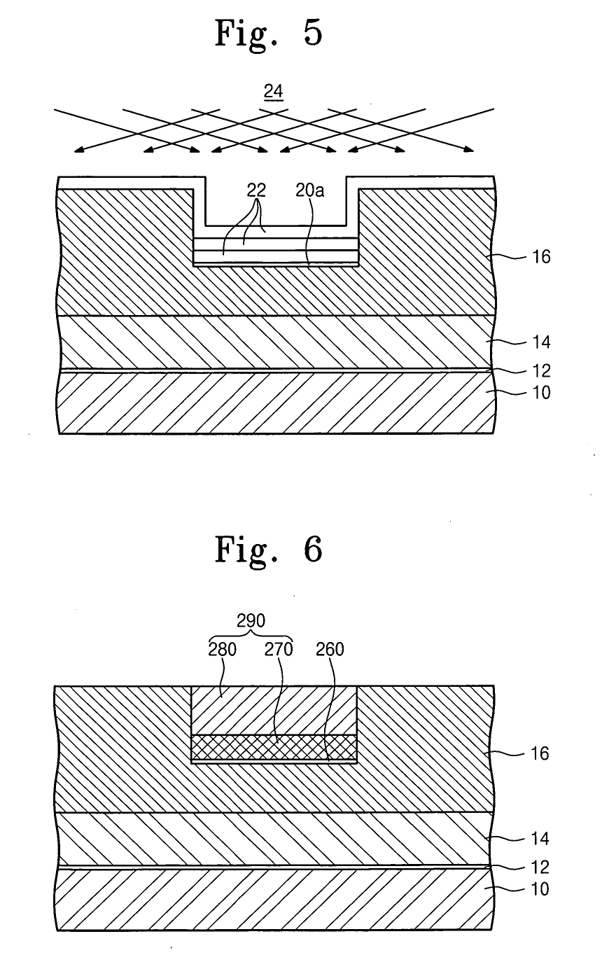

Referring to FIG. 4, the groove 18 may be filled with a top electrode 280 and the second tunneling insulating layer 260 on the second middle electrode layer 16 around the groove 18 may be removed. As shown in FIG. 5, the top electrode 280 may be limitedly formed in the groove 18 by performing a deposition and an oblique ion beam etching of a top electrode layer 22 repeatedly. The second tunneling insulating layer 20 on the second middle electrode layer 16 around the groove 18 and on the sidewalls of the groove 18 may be removed by the oblique ion beam etching. Thus, the second tunneling insulating layer 20a may remain only under the top electrode 280.

As shown in FIG. 5, if the oblique ion beam etching may be performed on the deposited top electrode layer 22, the top electrode layer 22 on the second middle electrode layer 16 exposed to the ion beam may be etched. A processing of an oblique ion beam 24 may be cut off by the second middle electrode layer 16. As a result, the top electrode layer 22 on the sidewalls of the groove 18 may be removed. The top electrode layer 22 may be continuously deposited in the groove 18 to fill the groove 18. The top electrode layer 22 may be deposited on the second tunneling insulating layer 20a as well as in the groove 18. The top electrode layer 22 deposited on the second middle electrode layer 16 around the groove 18 may be removed by a planarization process after the groove 18 is filled.

The top electrode layer 22 may be formed of a platinode metal layer. The second middle electrode layer 16 may be etched using the top electrode 280 as an etching mask to form the second middle electrode 240 as shown in FIG. 1. When the first middle electrode layer 14 is magnetic material, the first middle electrode layer 14 may be etched using an etch selectivity of the first middle electrode layer 14 to the top electrode 280 to form a first middle electrode 220 as shown in FIG. 1. The first tunneling insulating layer 12 and the bottom electrode layer 10 may be patterned to form the bottom electrode 200 and the first tunneling insulating layer 210 may remain under the first middle electrode 220 as shown in FIG. 1.

In example embodiments, the second tunneling insulating layer 260 of FIG. 1 may make a tunneling resistor switch over a predetermined or given voltage and the first tunneling insulating layer 210 of FIG. 1 may prevent or reduce the second tunneling insulating layer 260 from physically being broken. The second tunneling insulating layer 260 may be formed to have a width of about several tens nm or less using the top electrode 280 as the etching mask. The first tunneling insulating layer 210 may be formed to have a thickness from about several Å to about several tens Å to have a tunneling resistance similar to the second tunneling insulating layer 260. Thus, the bottom electrode 200 of FIG. 1 may not have to be self aligned using the top electrode 280 as the etching mask. The bottom electrode layer 10 may be formed of the platinode metal.

FIG. 6 is a cross sectional view illustrating a method of forming a storage of a non-volatile memory device according to example embodiments. Referring to FIG. 6, a top electrode 290 may include a first top electrode 270 and a second top electrode 280. The first top electrode 270 may be formed of tantalum and the second top electrode 280 may be formed of platinode metal. The top electrode 290 may be formed by a deposition of a top electrode layer and an oblique ion beam etching. A deposition and an oblique ion beam etching of a first top electrode layer may be repeatedly performed to form the first top electrode 270 and a deposition and an oblique ion beam etching of a second top electrode layer may be repeatedly performed on the first top electrode 270 to form the second top electrode 280. Subsequent processes may be performed according to the method of example embodiments to form a storage of a non-volatile memory device including the first and second top electrodes 270 and 280 as shown in FIG. 2.

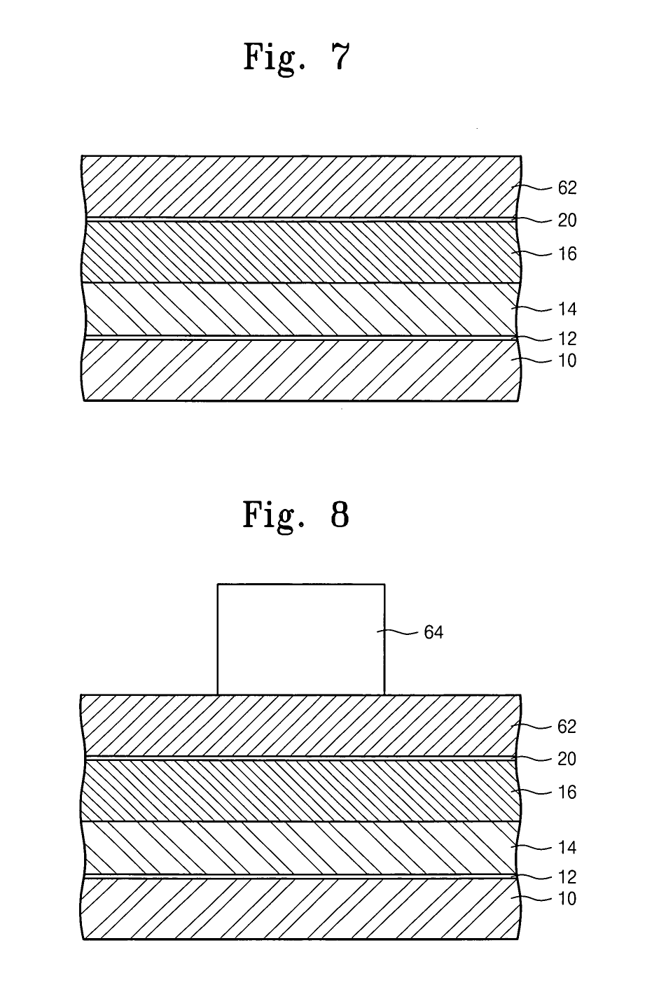

FIGS. 7 to 9 are cross sectional views illustrating a method of forming a storage of a non-volatile memory device according to example embodiments. Referring to FIG. 7, a bottom electrode layer 10, a first tunneling insulating layer 12, a first middle electrode layer 14, a second middle electrode layer 16, a second tunneling insulating layer 20 and a top electrode layer 62 may be formed.

The bottom electrode layer 10 may be formed of a platinode metal layer and/or magnetic material. The bottom electrode layer 10 may also be formed by stacking the magnetic material on the platinode metal layer. The first tunneling insulating layer 12 may be formed of a metal oxide layer, e.g., a magnesium oxide layer, an aluminum oxide layer and/or a titanium oxide layer. The first middle electrode layer 14 may also be formed of the platinode metal layer and/or magnetic material.

The second middle electrode layer 16 may be a material that may form a metal oxide layer and may be formed of a titanium layer or a titanium nitride layer. The second tunneling insulating layer 20 may be formed of an insulating layer by oxidizing the second middle electrode layer 16. The second tunneling insulating layer 20 may be formed of a titanium oxide layer. The titanium oxide layer may be formed by oxidizing the titanium layer or the titanium nitride layer of the second middle electrode layer 16. The titanium oxide layer may also be formed by wet cleaning after forming a second middle electrode layer 16. The top electrode layer 62 may be formed on the second tunneling insulating layer 20. The top electrode layer 62 may be formed of a platinode metal layer. The first and second tunneling insulating layers 12 and 20 may be formed to have thicknesses from about several Å to about several tens Å, for example, from about 5 Å to about 20 Å.

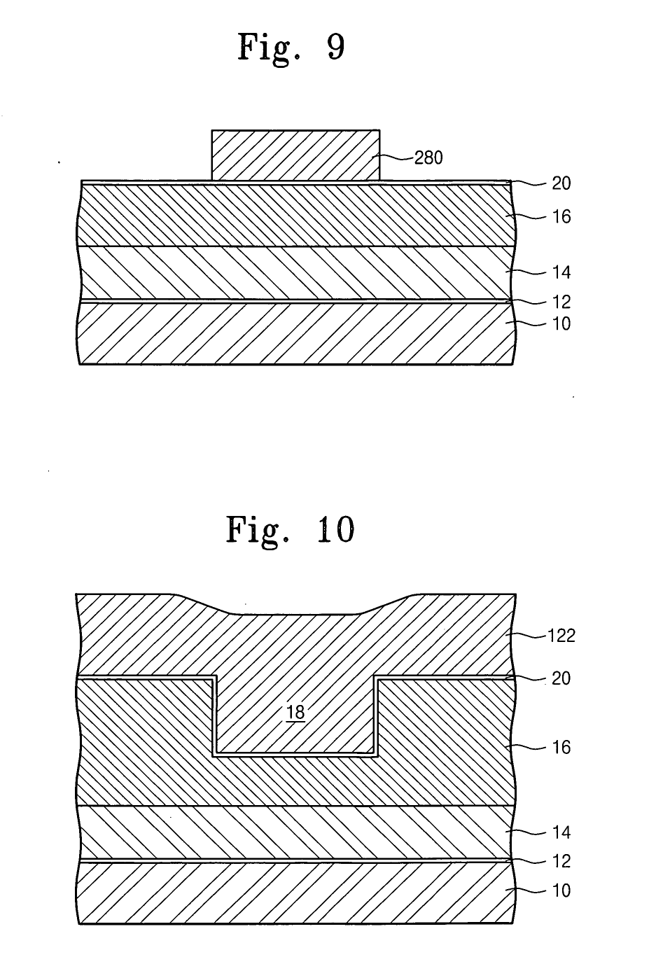

Referring to FIG. 8, a mask pattern 64 may be formed on the top electrode layer 62. The mask pattern 64 for forming the second tunneling insulating layer 20 may have a width of about several tens nm or less and may be formed of a photoresist pattern. The top electrode layer 62 may be etched using the mask pattern 64 as an etching mask. Referring to FIG. 9, the top electrode layer 62 may be etched to form a top electrode 280 and the mask pattern 64 may be removed. The mask pattern 64 may not be removed to be used as an etching mask of a subsequent process.

The second tunneling insulating layer 20 and the second middle electrode layer 16 may be patterned using the top electrode 280 as an etching mask to form the second middle electrode 240 as shown in FIG. 1 leaving the second tunneling insulating layer 260 underlying the top electrode 280 as shown in FIG. 1. An anisotropic etching may be performed in a condition of increased etch selectivity with respect to the second tunneling insulating layer 20 and the second middle electrode layer 16. The anisotropic etching may be performed using chlorine-base compound which may do not well react to a platinode element. Continuously, the first middle electrode layer 14, the first tunneling insulating layer 12 and the bottom electrode layer 10 may be etched to form the first middle electrode 220 and the bottom electrode 200 with the first tunneling insulating layer 210 between the bottom electrode 200 and the first middle electrode 220 shown in FIG. 1.

In example embodiments, the first middle and bottom electrodes 220 and 200 may be patterned to have a shape different from the second middle electrode 240. When the mask pattern 64 is on the top electrode 280, patterns underlying the second middle electrode 240 may be formed using the mask pattern 64 as an etching mask. In the case that the mask pattern 64 may be removed, after forming the second middle electrode 240, patterns underlying the second middle electrode 240 may be formed using another mask pattern as an etching mask.

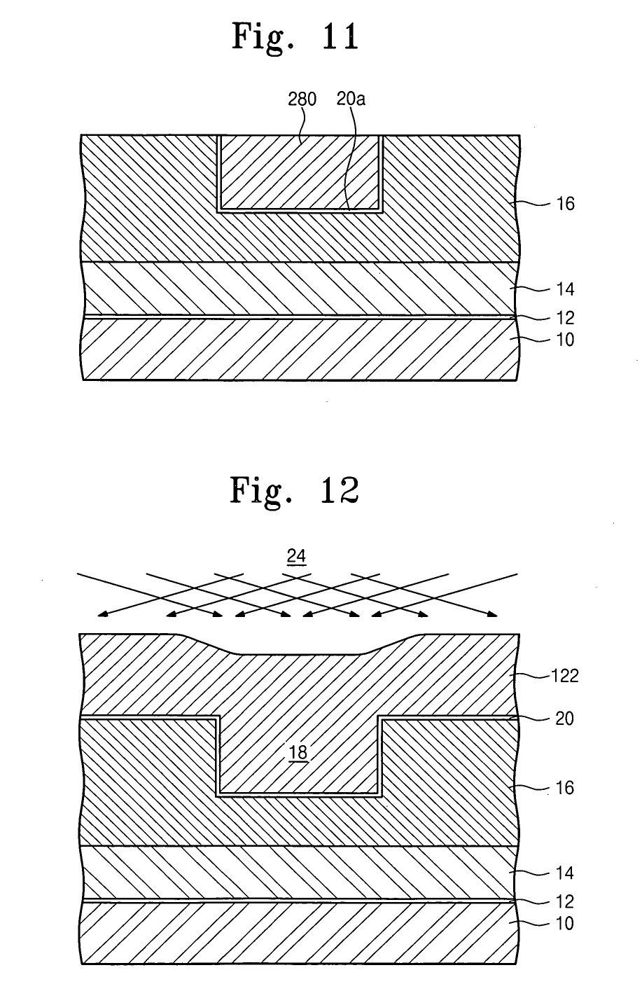

FIGS. 10 and 11 are cross sectional views illustrating a method of forming a storage of a non-volatile memory device according to example embodiments. Referring to FIG. 10, a bottom electrode layer 10, a first tunneling insulating layer 12, a first middle electrode layer 14 and a second middle electrode layer 16 may be formed. A portion of the second middle electrode layer 16 may be etched to form a groove 18 having a width of about several tens nm and a second tunneling insulating layer 20 may be formed on the second middle electrode layer 16. The second tunneling insulating layer 20 may be formed of variable resistor material. A top electrode layer 122 may be formed on the second tunneling insulating layer 20 to fill the groove 18.

The bottom electrode layer 10 may be formed of a platinode metal layer or magnetic material. The bottom electrode layer 10 may also be formed by stacking the magnetic material on the platinode metal layer. A platinode element may include ruthenium (Ru), rhodium (Rh), palladium (Pd), osmium (Os), iridium (Ir), and platinum (Pt). The magnetic material may include cobalt-ferrum-boron alloy or nickel-ferrum alloy. The bottom electrode layer 10 may be formed of at least one stacked layer selected from a group consisting of ruthenium (Ru), iridium (Ir), nickel (Ni), cobalt-ferrum-boron alloy and nickel-ferrum alloy.

The first tunneling insulating layer 12 may be formed of a metal oxide layer (e.g., a magnesium oxide layer, an aluminum oxide layer or a titanium oxide layer) to have a thickness from about 5 Å to about 20 Å. The first middle electrode layer 14 may also be formed of a platinode metal layer or magnetic material. The second middle electrode layer 16 may provide the second tunneling insulating layer 20 with a hole trap site and may be formed of metal that helps tunneling between the bands occur in the second tunneling insulating layer 20. For instance, the second tunneling insulating layer 20, e.g., a titanium oxide layer, may be more easily formed by forming the second middle electrode layer 16 of a titanium layer or a titanium nitride layer.

The top electrode layer 122 may be formed of platinode metal to improve an interface characteristic of the second tunneling insulating layer 20 and may be formed of material having an etch selectivity with respect to underlying material to form a storage patterning easily. A platinode metal layer may have an etch selectivity with respect to the titanium layer, the titanium nitride layer and the magnetic material.

Referring to FIG. 11, the top electrode layer 122 may be planarized to form a top electrode 280 which may be limitedly in the groove 18. The planarization of the top electrode layer 122 may be performed using a chemical mechanical polishing (CMP) process and an anisotropic etch back process. The top electrode 280 may be formed on the second tunneling insulating layer 20a which remains on a lower portion and sidewalls of the groove 18. Underlying material layers may be patterned using the top electrode 280 as an etching mask to form a second middle electrode 240 leaving a second tunneling insulating layer 260 under the top electrode 280 as shown in FIG. 1. Continuously, the first middle electrode 14, the first tunneling insulating layer 12 and the bottom electrode layer 10 may be patterned.

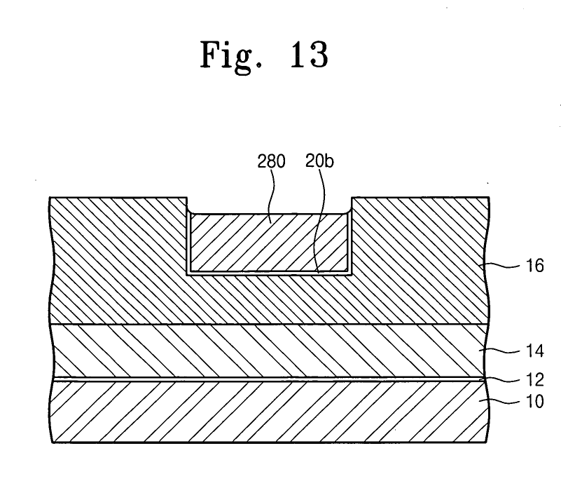

FIGS. 12 and 13 are cross sectional views illustrating a method of forming a storage of a non-volatile memory device according to example embodiments. Referring to FIG. 12, a bottom electrode layer 10, a first tunneling insulating layer 12, a first middle electrode layer 14 and a second middle electrode layer 16 may be formed. A top electrode layer 122 may be formed and then etched back. The top electrode layer 122 may be etched back using an oblique ion beam etching. A second tunneling insulating layer 20 and the top electrode layer 122 on a second middle electrode layer 16 may be etched to form a top electrode 280, as shown in FIG. 13, which may be limitedly in a groove 18. Though the top electrode 280 may be formed on a variable resistor insulating layer 20b which remains on a lower portion and sidewalls of the groove 18, an upper portion of the sidewalls of the groove 18 may be exposed by the oblique ion beam etching. Continuously, underlying material layers may be etched using the top electrode 280 as an etching mask to form the storage as shown in FIG. 1.

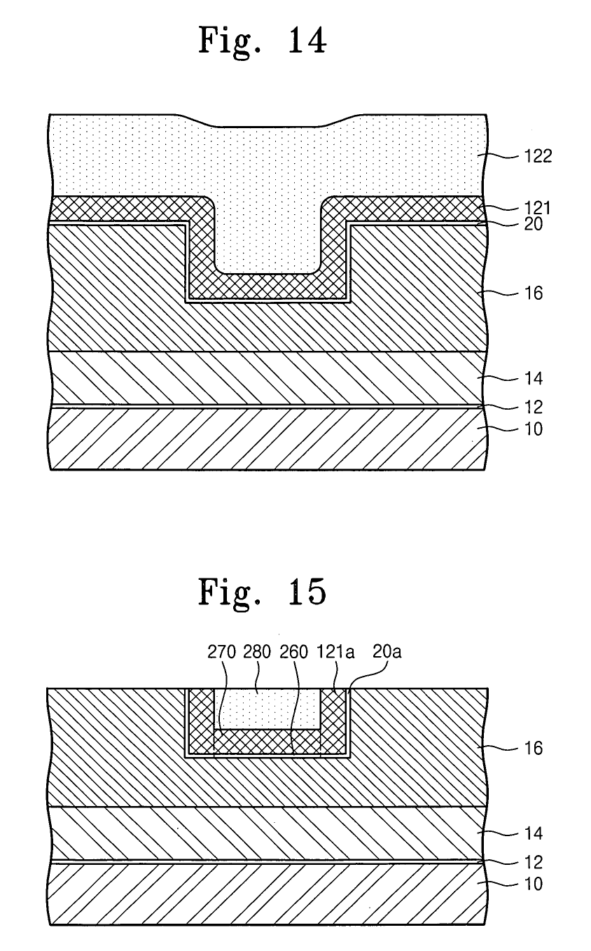

FIGS. 14 and 15 are cross sectional views illustrating a method of forming a storage of a non-volatile memory device according to example embodiments. Referring to FIG. 14, a bottom electrode layer 10, a first tunneling insulating layer 12, a first middle electrode layer 14 and a second middle electrode layer 16 may be formed. A first top electrode layer 121 and a second top electrode layer 122 may be formed on a second tunneling insulating layer 20. The first top electrode layer 121 may be formed of a tantalum layer and the second top electrode layer 122 may be formed of a platinode metal layer.

Referring to FIG. 15, the second and first top electrode layers 122 and 121 may be sequentially planarized to leave limitedly a second tunneling insulating layer 20a, a first top electrode layer 121a and a second top electrode 280 in the groove 18. The planarization process may be performed by a chemical mechanical polishing (CMP) process and an etch back process. The first top electrode layer 121 a and the second tunneling insulating layer 20a may be etched using the second top electrode 280 to form a first top electrode 270 and to leave a second tunneling insulating layer 260 under the first top electrode 270. Continuously, the second middle electrode layer 16 may be etched using the second top electrode 280 as an etching mask to form a second middle electrode 240 as shown in FIG. 1.

According to example embodiments, the second top electrode 280 may be formed in the first top electrode layer 121a which covers the lower portion and the sidewalls of the groove 18. Thus, the second top electrode 280 may be formed to be smaller than the groove 18. Because the first top electrode 270 and the second middle electrode layer 16 may be etched using chlorine-base compound, the second top electrode 280 may be used as an etching mask.

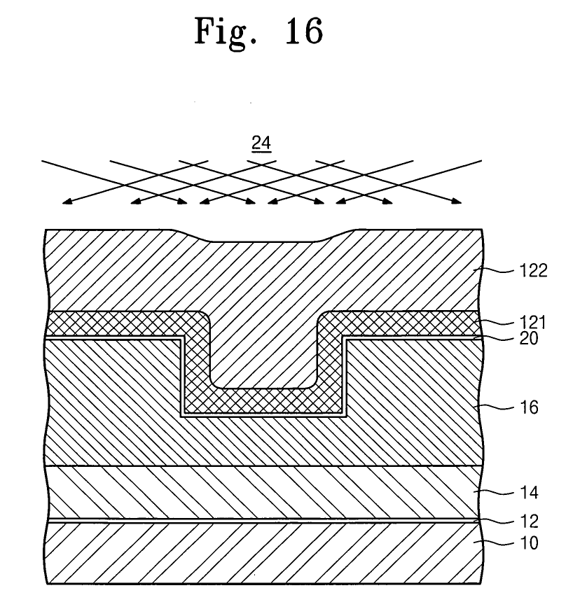

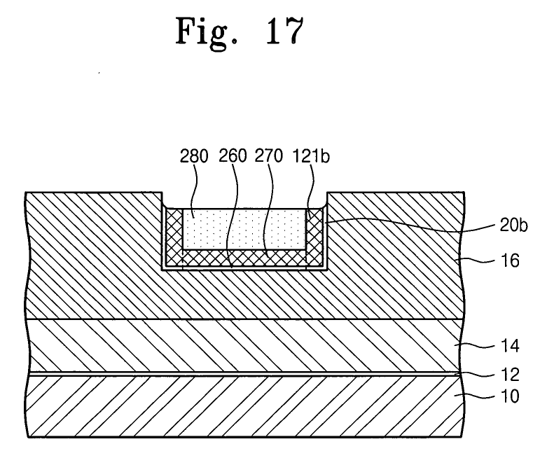

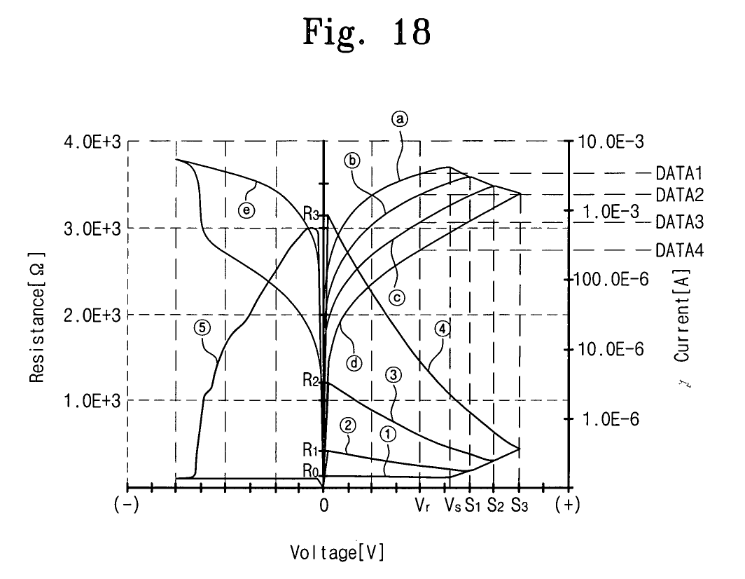

FIGS. 16 and 17 are cross sectional views illustrating a method of forming a storage of a non-volatile memory device according to example embodiments. Referring to FIG. 16, a bottom electrode layer 10, a first tunneling insulating layer 12, a first middle electrode layer 14 and a second middle electrode layer 16 may be formed. First and second top electrode layers 121 and 122 may be formed on a second tunneling insulating layer 20. The first and second top electrode layers 121 and 122 may be planarized by an oblique ion beam etching 24.

Referring to FIG. 17, a first top electrode 121b may remain limitedly in a groove 18 and a second top electrode 280 may be formed on the first top electrode 121b to fill the groove 18. The planarization process may be performed using a chemical mechanical polishing (CMP) process and an anisotropic etch back process. Though a second tunneling insulating layer 20b remains on the lower portion and the sidewalls of the groove 18, an upper portion of the sidewalls of the groove 18 may be exposed by an oblique ion beam etching 24. Thus, the first top electrode layer 121b and the second top electrode 280 may not fill the upper portion of the sidewalls of the groove 18.

The first top electrode layer 121b and the second tunneling insulating layer 20b may be etched using the second top electrode 280 as an etching mask to form a first top electrode 270 and to leave a second tunneling insulating layer 260 under the first top electrode 270. Continuously, the second middle electrode layer 16 may be etched using the second top electrode 280 as an etching mask to form the second middle electrode 240 as shown in FIG. 1.

In example embodiments, first and second tunneling insulating layers may be formed to have a width of about several tens nm. A dimension of an insulating layer may mean an effective dimension and the effective dimension may be determined by the electrodes overlying and underlying the insulating layer. Because the second tunneling insulating layer is disposed between a top electrode and a middle electrode, an effective width of the second tunneling insulating layer may be about several tens nm by forming the top electrode and the middle electrode to have a width of about several tens nm. Also, because the first tunneling insulating layer is disposed between the middle electrode and a bottom electrode, an effective width of the first tunneling insulating layer may be about several tens nm by forming the middle electrode to have a width of several tens nm.

FIG. 18 is a graph showing an operation characteristic of a non-volatile memory device according to example embodiments. A non-volatile memory device including a dual tunneling insulating layer may have a switching characteristic at more than a predetermined or given voltage. Because the tunneling insulating layer has a dual structure including first and second tunneling insulating layers, the tunneling insulating layer may have a voltage-current characteristic without a breakdown of the insulating layers according to a tunneling resistance.

In the graph, a horizontal axis indicates a voltage applied between the top and bottom electrodes. A left vertical axis indicates a resistance and a right vertical axis indicates a current. The resistance may be represented as a linear scale and the current may be represented as a log-scale. Lines \textcircled{1}˜\textcircled{5} may be voltage-resistance curves and lines \textcircled{a}˜\textcircled{e} may be voltage-current curves. Referring to FIG. 18, a plurality of switching voltages (S₁˜S₃) over an initial critical voltage Vs may be set. When the voltage falls after rising to each switching voltage, a voltage-resistance curve in a falling region of voltage may be different from a rising section of voltage. When starting at an initial resistance R₀ and falling after rising to a first switching voltage S₁ along a first curve \textcircled{1}, a resistance of a variable resistor may be a first switching R₁ returned along a second curve \textcircled{2}, and when rising to a second switching voltage S₂, the resistance of the variable resistor may be a second switching R₂ returned along a third curve \textcircled{3}, and when rising to a third switching voltage S₃, the resistance of the variable resistor may be a third switching R₃ returned along a fourth curve \textcircled{4}.

In a storage having the initial resistance R₀, when an applied voltage falls after rising to a voltage lower than the critical voltage Vs, a resistance returns along the same curve as the voltage rising section. If the applied voltage rises to an n-th switch voltage, the critical voltage Vs rises. When the applied voltage falls after rising to a voltage lower than a changed critical voltage, a resistance returns along an n+1 curve. The voltage-current curve according to a switching voltage may be represented by the voltage-resistance characteristic. If a plurality of switching voltages Sn may be set, a current value may return along different curves and the critical voltage may rise when an applied voltage falls after rising to each switching voltage Sn.

In an initial voltage rising section, when an applied voltage falls after rising to over the initial critical voltage Vs, the current-voltage curve may be changed and currents which increase along a first course a return along a second course b, a third course c and a fourth course d, respectively. After the initial critical voltage Vs rises according to each switching voltage and the current-voltage curve is switched, a current value may return along the voltage rising section when a voltage lower than a changed critical voltage is applied. By using this, the variable resistor may be used as a storage storing a multi-bit.

For example, data values may be given to a current value (data 1) of an initial variable resistor, a first switched current value (data 2), a second switched current value (data 3) and a third switched current value (data 4), respectively, to store 2 bit by setting a read voltage Vr lower than the initial critical voltage Vs and measuring current flowing through the variable resistor. A voltage having a polarity opposite to an applied voltage for data programming may be applied to the variable resistor to reset the variable resistor to an initial state. If the voltage having a polarity opposite to the applied voltage for data programming is applied to the variable resistor, a resistance may be abruptly reduced like a fifth curve \textcircled{5} and an absolute value of the current may be initialized along a fifth course e.

While example embodiments have been particularly shown and described with reference to example embodiments thereof, it will be understood by one of ordinary skill in the art that various changes in form and details may be made therein without departing from the spirit and scope of the following claims.

What is claimed is:

1. A storage of a non-volatile memory device, comprising:
a bottom electrode;
a first tunneling insulating layer on the bottom electrode;
a middle electrode on the first tunneling insulating layer;
a second tunneling insulating layer on the middle electrode; and
a top electrode on the second tunneling insulating layer.

2. The storage of claim 1, wherein the first tunneling insulating layer has a thickness from about 5 Å to about 20 Å.

3. The storage of claim 1, wherein the second tunneling insulating layer has a thickness from about 5 Å to about 20 Å.

4. The storage of claim 1, wherein the second tunneling insulating layer has a width of less than about 100 nm.

5. The storage of claim 1, wherein the first tunneling insulating layer between the bottom and middle electrodes has a width of about 100 nm or less.

6. The storage of claim 1, wherein the first and second tunneling insulating layers include a metal oxide layer.

7. The storage of claim 6, wherein the first tunneling insulating layer includes one selected from a magnesium oxide layer, an aluminum oxide layer and a titanium oxide layer.

8. The storage of claim 6, wherein the second tunneling insulating layer includes a titanium oxide layer.

9. The storage of claim 1, wherein the middle electrode on the first tunneling insulating layer includes platinode element or magnetic material.

10. The storage of claim 9, wherein the middle electrode on the first tunneling insulating layer includes one selected from ruthenium, iridium, nickel, cobalt-ferrum-boron alloy and nickel-ferrum alloy.

11. The storage of claim 1, wherein the middle electrode under the second tunneling insulating layer includes a titanium layer or a titanium nitride layer.

12. The storage of claim 11, wherein the second tunneling insulating layer includes a titanium oxide layer.

13. The storage of claim 1, wherein the top electrode includes platinode element.

14. The storage of claim 13, the top electrode further includes a tantalum layer between the platinode element and the second tunneling insulating layer.

15. The storage of claim 1, wherein the bottom electrode includes platinode element or magnetic material.

16. The storage of claim 1, wherein the first and second tunneling insulating layers have a tunneling resistance of the same level.

17. The storage of claim 1, wherein the bottom electrode and top electrode in contact with the first tunneling insulating layer include a magnetic material.

18. The storage of claim 17, wherein the second tunneling insulating layer includes a titanium oxide layer.

19. The storage of claim 18, wherein the second tunneling insulating layer has a width of less than about 100 nm and is self aligned to the top electrode.

20. A method of forming a storage of a non-volatile memory device, comprising:
forming a first tunneling insulating layer on a bottom electrode;
forming a middle electrode on the first tunneling insulating layer;
forming a second tunneling insulating layer on the middle electrode; and
forming a top electrode on the second tunneling insulating layer.

21. The method of claim 20, wherein forming the top electrode comprises:
forming a middle electrode layer;
etching the middle electrode layer to a depth to form a groove;
forming the second tunneling insulating layer on a surface of the middle electrode layer in the groove; and
forming the top electrode on the second tunneling insulating layer to fill the groove.

22. The method of claim 21, wherein the middle electrode layer is formed of a titanium layer or a titanium nitride layer.

23. The method of claim 21, wherein forming the middle electrode layer comprises:
forming a first middle electrode layer including a platinode element or a magnetic material; and
forming a second middle electrode layer including a titanium layer or a titanium nitride layer on the first middle insulating layer.

24. The method of claim 21, wherein the second tunneling insulating layer is formed of a titanium oxide layer, wherein the titanium oxide layer is formed by oxidizing a titanium layer or a titanium nitride layer.

25. The method of claim 24, wherein the titanium layer or the titanium nitride layer is oxidized in a cleaning process after forming the groove.

26. The method of claim 21, wherein a deposition and an oblique ion beam etching of a top electrode layer are repeatedly performed to form the top electrode on the second tunneling insulating layer of a lower portion of the groove.

27. The method of claim 26, wherein the second tunneling insulating layer on sidewalls of the groove and an around the groove is removed.

28. The method of claim 21, wherein forming the top electrode comprises:
forming a top electrode layer on the middle electrode layer including the second tunneling insulating layer; and
planarizing the top electrode layer and the second tunneling insulating layer sequentially to form the top electrode filling the groove.

29. The method of claim 28, wherein the planarization process is performed using a chemical mechanical polishing (CMP) process, an etch back process or an oblique ion beam etching process.

30. The method of claim 21, wherein forming the middle electrode includes patterning the second tunneling insulating layer and the middle electrode layer using the top electrode as an etching mask.

31. The method of claim 21, wherein the top electrode includes a first top electrode and a second top electrode on the first top electrode,
wherein the first top electrode is formed of a tantalum layer and the second top electrode is formed of a platinode element or a magnetic material.

32. The method of claim 31, wherein the first top electrode is formed on the second tunneling insulating layer of the lower portion of the groove and the second top electrode is formed on the first top electrode to be in contact with the sidewalls of the groove.

33. The method of claim 32, wherein the first top electrode is partially formed on the second tunneling insulating layer of the lower portion of the groove by performing a deposition and an oblique ion beam etching of a first top electrode layer repeatedly, and wherein the second top electrode is formed on the first top electrode to fill the groove partially by performing a deposition and an oblique ion beam etching of a second top electrode layer repeatedly.

34. The method of claim 31, wherein forming the first and second top electrodes comprise:
forming a first top electrode layer on the second tunneling insulating layer to cover the lower portion and sidewalls of the groove with a depth;
forming a second top electrode layer on the first top electrode layer to fill the groove; and
planarizing the first and second top electrode layers to form the first top electrode of a cylinder type and the second top electrode filling a space of the first top electrode in the groove.

35. The method of claim 34, wherein the planarization process is performed using a chemical mechanical polishing (CMP) process, an etch back process or an oblique ion beam etching process.

36. The method of claim 34, wherein forming the middle electrode includes patterning the second tunneling insulating layer and the middle electrode layer using the second top electrode as an etching mask.
